(19) United States
(12) Patent Application Publication
(10) Pub. No.: US 2024/0081128 A1
(43) Pub. Date: Mar. 7, 2024

(54) DISPLAY DEVICE AND METHOD FOR MANUFACTURING THE SAME

(71) Applicant: Samsung Display Co., Ltd., Yongin-si (KR)

(72) Inventor: KYONGTAE YU, Yongin-si (KR)

(73) Assignee: Samsung Display Co., Ltd., Yongin-si (KR)

(21) Appl. No.: 18/338,481

(22) Filed: Jun. 21, 2023

(30) Foreign Application Priority Data
Sep. 5, 2022 (KR) 10-2022-0111969

(51) Int. Cl. H10K 59/80; H10K 59/122; H10K 71/13

(52) U.S. Cl. CPC H10K 59/8051; H10K 59/122; H10K 59/8052; H10K 71/135; H10K 2102/351

(57) ABSTRACT

A method for manufacturing a display device, includes discharging ink containing a solvent onto a substrate to form a preliminary functional layer, providing a temperature control member on a lower surface of the substrate, providing a drying member having a plurality of thermally conductive balls on an upper surface of the substrate, and drying the preliminary functional layer by the drying member.

### CROSS-REFERENCE TO RELATED APPLICATIONS

This application claims priority to and benefits of Korean Patent Application No. 10-2022-0111969 under 35 U.S.C. § 119, filed in the Korean Intellectual Property Office on Sep. 5, 2022, the entire contents of which are incorporated herein by reference.

### BACKGROUND

### 1. Technical Field

The disclosure herein relates to a display device and a method of manufacturing the same, and more specifically, to a display device with improved display quality and a method of manufacturing the same.

### 2. Description of the Related Art

An inkjet printing method is used in manufacturing a light emitting element included in various electronic devices, for example, multimedia devices such as a television, a mobile phone, a tablet computer, a navigation system, and a game console. Functional layers such as an optical pattern, a color filter, or a light emitting layer of a display panel, may be formed using an inkjet printing apparatus. For example, components constituting a display panel may be formed by discharging inkjet printing ink to a target substrate.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device with improved display quality.

Embodiments also provide a method of manufacturing a display device with improved display quality.

However, embodiments of the disclosure are not limited to those set forth herein. The above and other embodiments will become more apparent to one of ordinary skill in the art to which the disclosure pertains by referencing the detailed description of the disclosure given below.

An embodiment of the disclosure provides a method of manufacturing a display device including discharging ink containing a solvent onto a substrate to form a preliminary functional layer, providing a temperature control member on a lower surface of the substrate, providing a drying member including a plurality of thermally conductive balls on an upper surface of the substrate, and drying the preliminary functional layer by the drying member.

In an embodiment, the method may further include adjusting a distance between the drying member and the substrate.

In an embodiment, the solvent may be vaporized and pass through the plurality of thermally conductive balls.

In an embodiment, the plurality of thermally conductive balls may include a silicon oxide polymer.

In an embodiment, the drying member may further include an outer plate, and the plurality of thermally conductive balls may be surrounded by the outer plate.

In an embodiment, the drying member may further include a first mesh member attached to a lower surface of the outer plate and a second mesh member attached to an upper surface of the outer plate. The plurality of thermally conductive balls may be disposed in a space surrounded by the outer plate, the first mesh member, and the second mesh member.

In an embodiment, a plurality of openings may be defined in the first mesh member and the second mesh member, and a width of each of the plurality of openings may be smaller than a diameter of each of the plurality of thermally conductive balls.

In an embodiment, the outer plate may have a thickness in a range of about 5 mm to about 1 cm.

In an embodiment, the distance between the substrate and the drying member may be in a range of about 10 mm to about 100 mm.

In an embodiment, the substrate may completely overlap the drying member in a plan view.

In an embodiment, the providing of the drying member may include adjusting a height of the plurality of thermally conductive balls to adjust a pressure difference of the plurality of thermally conductive balls.

In an embodiment of the disclosure, a display device includes a circuit layer disposed on a base layer, a first light emitting element disposed on the circuit layer and including a 1-1-th electrode, a 1-1-th functional layer, a first light emitting layer, a 2-1-th functional layer, and a 2-1-th electrode, a second light emitting element disposed on the circuit layer and including a 1-2-th electrode, a 1-2-th functional layer, a second light emitting layer, a 2-2-th functional layer, and a 2-2-th electrode, and a pixel defining film disposed on the circuit layer and including a first opening exposing a top surface of the 1-1-th electrode, and a second opening exposing a top surface of the 1-2-th electrode. The 1-1-th electrode, the 1-1-th functional layer, the first light emitting layer, the 2-1-th functional layer, and the 2-2-th electrode are sequentially stacked. The 1-1-th functional layer, the first light emitting layer, and the 2-1-th functional layer are disposed in the first opening. The 1-2-th functional layer, the second light emitting layer, and the 2-2-th functional layer may be disposed in the second opening. A thickness of the 1-1-th functional layer is uniform in the first opening, and a thickness of the 1-2-th functional layer is uniform in the second opening.

In an embodiment, the thickness of the 1-1-th functional layer and the thickness of the 1-2-th functional layer may be substantially the same.

In an embodiment, a thickness of the 2-1-th functional layer and a thickness of the 2-2-th functional layer may be substantially the same.

In an embodiment, the 1-1-th functional layer, the first light emitting layer, and the 2-1-th functional layer may each be provided through an inkjet printing method.

In an embodiment, the 1-2-th functional layer, the second light emitting layer, and the 2-2-th functional layer may each be provided through an inkjet printing method.

In an embodiment, within a distance of about 5 micrometers from the pixel defining film, the thickness of the 1-1-th functional layer and the thickness of the 1-2-th functional layer may have a uniformity of about 1% or less.

In an embodiment, the 1-1-th electrode may be parallel to a first portion of the 2-1-th electrode overlapping the 1-1-th electrode in a plan view.

In an embodiment, the 1-2-th electrode may be parallel to a second portion of the 2-2-th electrode overlapping the 1-2-th electrode in a plan view.

In an embodiment, a thickness of the 2-1-th functional layer may be uniform in the first opening and a thickness of the 2-2-th functional layer may be uniform in the second opening.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic plan view of a display device according to an embodiment of the disclosure;

FIG. 2 is a schematic cross-sectional view of a display device according to an embodiment of the disclosure;

FIG. 3 is a flowchart schematically illustrating a method of manufacturing a display device according to an embodiment of the disclosure;

FIG. 4 is a schematic diagram illustrating a part of a method of manufacturing a display device according to an embodiment of the disclosure;

FIG. 5 is a schematic diagram illustrating a part of a method of manufacturing a display device according to an embodiment of the disclosure;

FIG. 6 is a schematic plan view illustrating a drying member and a substrate according to an embodiment of the disclosure; and

FIG. 7 is a schematic diagram illustrating a part of a method of manufacturing a display device according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure are described in detail with reference to the accompanying drawings.

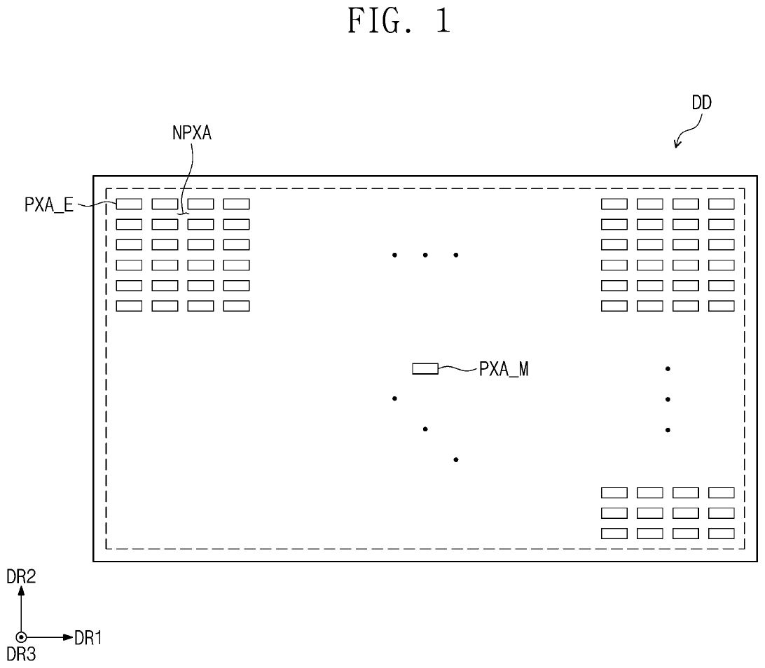

FIG. 1 is a schematic plan view of a display device DD according to an embodiment of the disclosure.

Referring to FIG. 1, the display device DD may include light emitting regions PXA_E and PXA_M. The light emitting regions PXA_E and PXA_M may respectively be a blue light emitting region emitting blue light, a green light emitting region emitting green light, or a red light emitting region emitting red light. However, an embodiment of the disclosure is not limited thereto, and the light emitting regions PXA_E and PXA_M may further include a region that emits white light or a light emitting region that emits light in a wavelength range other than blue, green, and red.

The light emitting regions PXA_E and PXA_M may be separated from each other and may not overlap each other in a plan view (e.g., on a plane defined by a first direction DR1 and a second direction DR2). A non-light emitting region NPXA may be disposed between adjacent light emitting regions PXA_E and PXA_M.

Hereinafter, the first direction DR1, the second direction DR2, and the third direction DR3 are illustrated, and the directions indicated by the first to third direction DR1, DR2, and DR3 described herein may have a relative concept and may be changed to other directions. In the specification, the first direction DR1 and the second direction DR2 may be perpendicular to each other, and the third direction DR3 may be a normal direction of the plane defined by the first direction DR1 and the second direction DR2.

In the specification, a thickness direction of the display device DD may be parallel to the third direction DR3 which is a normal direction of the plane defined by the first direction DR1 and the second direction DR2. In the specification, a front surface (or an upper surface) and a rear surface (or a lower surface) of each member constituting the display device DD may be defined based on the third direction DR3.

The light emitting regions PXA_M and PXA_E may include central light emitting regions PXA_M adjacent to a central portion of the display device DD and edge light emitting regions PXA_E adjacent to an edge portion of the display device DD.

In the display device DD illustrated in FIG. 1, the light emitting regions PXA_M and PXA_E are illustrated to be arranged in a stripe shape. However, an arrangement of the light emitting regions PXA_M and PXA_E is not limited to the arrangement illustrated in FIG. 1. The light emitting regions PXA_M and PXA_E may be provided in various arrangements and combinations according to the characteristics of display quality required for the display device DD. For example, an arrangement shape of the light emitting regions PXA_M and PXA_E may be a PenTile® (or PENTILE®) arrangement shape or a diamond arrangement shape. Areas of the light emitting regions PXA_M and PXA_E, a combination and the numbers of the light emitting regions emitting different lights, PXA_M and PXA_E, and planar shapes of the light emitting regions PXA_M and PXA_E may be variously adjusted or modified according to the characteristics of display quality required for the display device DD.

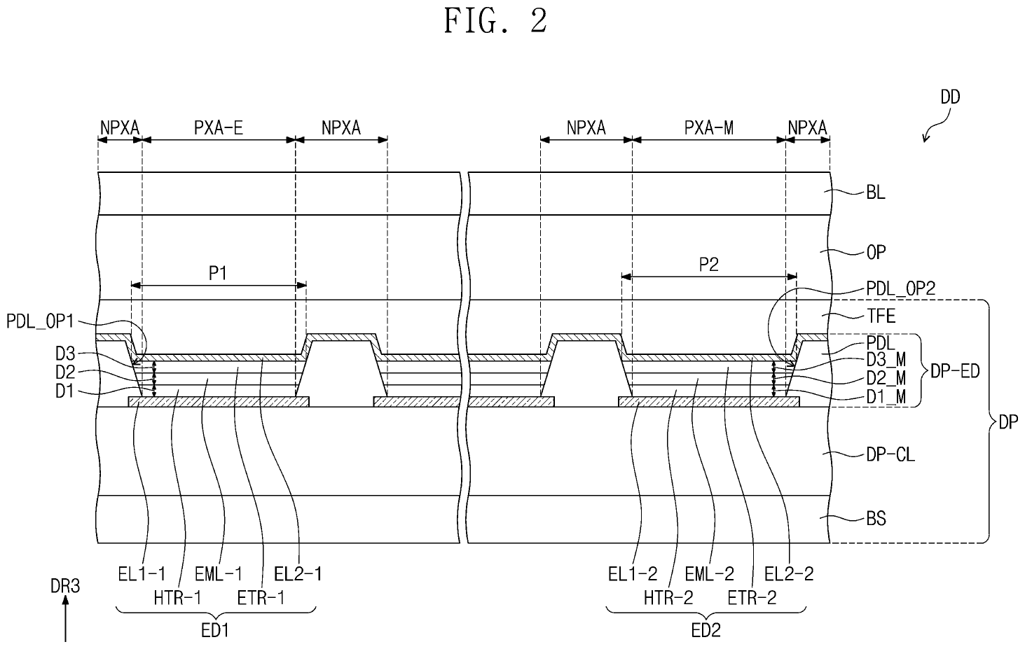

FIG. 2 is a schematic cross-sectional view of a display device DD according to an embodiment of the disclosure. FIG. 2 illustrates a schematic cross-section of the central light emitting region PXA_M and the edge light emitting region PXA_E.

Referring to FIG. 2, the display device DD may include a display panel DP, an optical control panel OP, and a base substrate BL.

The display panel DP may include a base layer BS, a circuit layer DP-CL provided on the base layer BS, a light emitting element layer DP-ED disposed on the circuit layer DP-CL, and an encapsulation layer TFE disposed on the light emitting element layer DP-ED.

The base layer BS may be a member that provides a base surface on which the circuit layer DP-CL is disposed. The base layer BS may be a rigid substrate or a flexible substrate capable of bending, folding, rolling, or the like.

The base layer BS may be a glass substrate, a metal substrate, or a polymer substrate. However, an embodiment of the disclosure is not limited thereto, and the base layer BS may include at least one of an inorganic layer, an organic layer, and a composite material layer. The base layer BS may have a multi-layer structure. For example, the base layer BS may include a first synthetic resin layer, an intermediate layer having a multi-layer or single-layer structure, and a second synthetic resin layer disposed on the intermediate layer. For example, the first synthetic resin layer, the intermediate layer, and the second synthetic resin layer may be stacked one another. Each of the first synthetic resin layer and the second synthetic resin layer may be an organic layer formed of a polymer material. In an embodiment, the base layer BS may include an organic layer formed of a transparent polyimide.

The circuit layer DP-CL may be disposed on the base layer BS. The circuit layer DP-CL may include an insulating layer, a semiconductor pattern, a conductive pattern, a signal line, or the like, or a combination thereof. An insulating layer, a semiconductor layer, and a conductive layer may be formed on the base layer BS through coating, depositing, or the like. The insulating layer, the semiconductor layer, and the conductive layer may be selectively patterned by performing a photolithography process multiple times. Thus, a semiconductor pattern, a conductive pattern, and a signal line included in the circuit layer DP-CL may be formed.

The circuit layer DP-CL may include transistors. Each of the transistors may include a control electrode, an input electrode, and an output electrode. For example, the circuit layer DP-CL may include a switching transistor and a driving transistor for driving light emitting elements ED1 and ED2 of the light emitting element layer DP-ED.

The light emitting element layer DP-ED may be disposed on the circuit layer DP-CL. The light emitting element layer DP-ED may include the light emitting elements ED1 and ED2. The light emitting elements ED1 and ED2 may include a first light emitting element ED1 and a second light emitting element ED2. The light emitting regions PXA_E and PXA_M may be regions in which light generated from the first and second light emitting elements ED1 and ED2 are emitted. For example, the edge light emitting regions PXA_E may correspond to the first light emitting elements ED1, and the central light emitting regions PXA_M may correspond to the second light emitting elements ED2. The light emitting regions PXA_E and PXA_M may be regions divided by a pixel-defining film PDL. The non-light emitting regions NPXA may be regions between adjacent light emitting regions PXA_E and PXA_M and may correspond to the pixel-defining film PDL. In the specification, each of the light emitting regions PXA_E and PXA_M may correspond to a pixel.

The first and second light emitting elements ED1 and ED2 may emit light in different wavelength ranges. For example, each of the light emitting elements ED1 and ED2 may include a light emitting element that emits blue light, green light, or red light. The first and second light emitting elements ED1 and ED2 may emit light having a same wavelength range. In other embodiments, the first light emitting elements ED1 may emit light having a wavelength range different from the second light emitting elements ED2. For example, the first and second light emitting elements ED1 and ED2 may emit blue light.

The first light emitting element ED1 may include a 1-1-th electrode EL1-1, a 2-1-th electrode EL2-1 facing the 1-1-th electrode EL1-1, and functional layers disposed between the 1-1-th electrode EL1-1 and the 2-1-th electrode EL2-1. The functional layers may include a 1-1-th functional layer HTR-1 (hereinafter, a first hole transport region), a light emitting layer EML-1, and a 2-1-th functional layer ETR-1 (hereinafter, a first electron transport region).

The second light emitting element ED2 may include a 1-2-th electrode EL1-2, a 2-2-th electrode EL2-2 facing the 1-2-th electrode EL1-2, and functional layers disposed between the 1-2-th electrode EL1-2 and the 2-2-th electrode EL2-2. The functional layers may include a 1-2-th functional layer HTR-2 (hereinafter, a second hole transport region), a light emitting layer EML-2, and a 2-2-th functional layer ETR-2 (hereinafter, a second electron transport region).

The first electrodes EL1-1 and EL1-2 may be disposed on the circuit layer DP-CL. The first electrodes EL1-1 and EL1-2 may be formed of a metal material, a metal alloy, or a conductive compound. The first electrodes EL1-1 and EL1-2 may be anodes.

Each of the first electrodes EL1-1 and EL1-2 may be a transmissive electrode, a transflective electrode, or a reflective electrode. In case that the first electrodes EL1-1 and EL1-2 are transmissive electrodes, the first electrodes EL1-1 and EL1-2 may include a transparent metal oxide, for example, indium tin oxide (ITO), indium zinc oxide (IZO), zinc oxide (ZnO), indium tin zinc oxide (ITZO), or the like, or a combination thereof. In case that the first electrodes EL1-1 and EL1-2 are transflective electrodes or reflective electrodes, the first electrodes EL1-1 and EL1-2 may include at least one of Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, and W. For example, the first electrodes EL1-1 and EL1-2 may include a compound or mixture thereof (e.g., mixture of Ag and Mg). In other embodiments, the first electrodes EL1-1 and EL1-2 may have a multilayer structure including at least one of a reflective film, a semi-transmissive film, and a transparent conductive film. Each of the reflective film and the semi-transmissive film may be formed of the above-described materials, and the transparent conductive film may include of indium tin oxide (ITO), indium zinc oxide (IZO), zinc oxide (ZnO), indium tin zinc oxide (ITZO), or the like, or a combination thereof. For example, the first electrodes EL1-1 and EL1-2 may have a three-layer structure of ITO/Ag/ITO, but are not limited thereto. An embodiment of the disclosure is not limited to the description above, and the first electrodes EL1-1 and EL1-2 may be formed of the above-described metal materials, a combination of two or more metal materials described above, or oxides of the above-described metal materials.

The hole transport regions HTR-1 and HTR-2 may be disposed on the first electrodes EL1-1 and EL1-2. For example, the first hole transport region HTR-1 may be accommodated (or disposed) in the first opening PDL-OP1 defined in the pixel defining film PDL, and disposed on the 1-1-th electrode EL1-1. The second hole transport region HTR-2 may be accommodated (or disposed) in the second opening PDL-OP2 defined in the pixel defining film PDL, and disposed on the 1-2-th electrode EL1-2.

The hole transport regions HTR-1 and HTR-2 (or each of the hole transport regions HTR-1 and HTR-2) may include at least one of a hole injection layer, a hole transport layer, a buffer layer, a light emitting auxiliary layer, and an electron blocking layer. The hole transport regions HTR-1 and HTR-2 may have a single layer composed of a single material, a single layer composed of different materials, or a multilayer structure having layers composed of different materials.

A thickness D1 of the first hole transport region HTR-1 may be uniform in the first opening PDL_OP1, and a thickness D1_M of the second hole transport region HTR-2 may be uniform in the second opening PDL_OP2. The thickness D1 of the first hole transport region HTR-1 and the thickness D1_M of the second hole transport region HTR-2 may be substantially the same.

The first light emitting layer EML-1 may be disposed on the first hole transport region HTR-1, and may be accommodated (or disposed) in the first opening PDL_OP1 defined in the pixel defining film PDL. For example, the first light emitting layer EML-1 may be formed separately to correspond to the edge light emitting region PXA_E divided by the pixel defining film PDL. For example, the first light emitting layer EML-1 may be disposed in the edge light emitting region PXA_E and spaced apart from an adjacent first light emitting layer EML-1. The second light emitting layer EML-2 may be disposed on the second hole transport region HTR-2, and may be accommodated (or disposed) in the second opening PDL_OP2 defined in the pixel defining film PDL. For example, the second light emitting layer EML-2 may be formed separately to correspond to the central light emitting region PXA_M divided by the pixel defining film PDL. For example, the second light emitting layer EML-2 may be disposed in the central light emitting region PXA_M and spaced apart from an adjacent second light emitting layer EML-2.

The first and second light emitting layers EML-1 and EML-2 may each emit at least one of the blue, red, or green light. The first and second light emitting layers EML-1 and EML-2 may include a fluorescent or phosphorescent material that emits red, green, or blue light. The first and second light emitting layers EML-1 and EML-2 may include a metal-organic complex as a light emitting material. The first and second light emitting layers EML-1 and EML-2 may include quantum dots as a light emitting material.

A thickness D2 of the first light emitting layer EML-1 may be uniform in the first opening PDL_OP1, and thickness D2_M of the second light emitting layer EML-2 may be uniform in the second opening PDL_OP2. The thickness D2 of the first light emitting layer EML-1 and the thickness D2_M of the second light emitting layer EML-2 may be substantially the same.

The electron transport regions ETR-1 and ETR-2 may be disposed on the first and second light emitting layers EML-1 and EML-2. For example, the first electron transport region ETR-1 may be accommodated (or disposed) in the first opening PDL-OP1 defined in the pixel defining film PDL, and may be disposed on the first light emitting layer EML-1. The second electron transport region ETR-2 may be accommodated (or disposed) in the second opening PDL-OP2 defined in the pixel defining film PDL, and may be disposed on the first light emitting layer EML-2.

The electron transport regions ETR-1 and ETR-2 may include at least one of a hole blocking layer, an electron transport layer, and an electron injection layer, but an embodiment of the disclosure is not limited thereto. The electron transport regions ETR-1 and ETR-2 (or each of the electron transport regions ETR-1 and ETR-2) may have a single layer composed of a single material, a single layer composed of different materials, or a multilayer structure having layers composed of different materials.

A thickness D3 of the first electron transport regions ETR-1 may be uniform in the first opening PDL_OP1, and a thickness D3_M of the second electron transport regions ETR-2 may be uniform in the second opening PDL_OP2. The thickness D3 of the first light emitting region ETR-1 and the thickness D3_M of the second light emitting region ETR-2 may be substantially the same.

In an embodiment of the disclosure, the hole transport regions HTR-1 and HTR-2, the light emitting layers EML-1 and EML-2, the electron transport regions ETR-1 and ETR-2, or the like may be provided through an inkjet printing method. The hole transport regions HTR-1 and HTR-2, the light emitting layers EML-1 and EML-2, and the electron transport regions ETR-1 and ETR-2 may be provided (e.g., sequentially provided) using the inkjet printing method. The hole transport regions HTR-1 and HTR-2, the light emitting layers EML-1 and EML-2, or the electron transport regions ETR-1 and ETR-2 may be formed by providing a hole transport material, a light emitting layer material, or an electron transport material as a printing layer solution together with a solvent. In other embodiments, the hole transport regions HTR-1 and HTR-2, the light emitting layers EML-1 and EML-2, or the electron transport regions ETR-1 and ETR-2 may be formed, without a separate solvent, from a hole transport compound, a light emitting layer compound, or an electron transport compound.

The 2-1-th electrode EL2-1 may be provided on the first electron transport regions ETR-1, and the 2-2-th electrode EL2-2 may be provided on the second electron transport regions ETR-2. The 2-1-th electrode EL2-1 and the 2-2-th electrode EL2-2 may be integral with each other. The second electrodes EL2-1 and EL2-2 may be a common electrode. The second electrodes EL2-1 and EL2-2 may be cathodes, but an embodiment of the disclosure is not limited thereto. For example, in case that the first electrodes EL1-1 and EL1-2 are anodes, the second electrodes EL2-1 and EL2-2 may be cathodes. in case that the first electrodes EL1-1 and EL1-2 are cathodes, the second electrodes EL2-1 and EL2-2 may be anodes. The second electrodes EL2-1 and EL2-2 may include at least one selected from Ag, Mg, Cu, Al, Pt, Pd, Au, Ni, Nd, Ir, Cr, Li, Ca, LiF, Mo, Ti, W, In, Sn, and Zn. In other embodiments, the second electrodes EL2-1 and EL2-2 may include a compound of at least two selected from the above-described materials, a mixture of at least two selected from the above-described materials, or oxides thereof.

The second electrodes EL2-1 and El2-2 may be a transmissive electrode, a transflective electrode, or a reflective electrode. In case that the second electrodes EL2-1 and EL2-2 are a transmissive electrode, the second electrodes EL2-1 and EL2-2 may be formed of transparent metal oxides, for example, ITO (indium tin oxide), IZO (indium zinc oxide), ZnO (zinc oxide), ITZO (indium tin zinc oxide), or the like, or a combination thereof.

In case that the second electrodes EL2-1 and EL2-2 are transflective or reflective electrodes, the second electrodes EL2-1 and EL2-2 may include at least one of Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, and W. In other embodiments, the second electrodes EL2-1 and EL2-2 may include a compound or mixture thereof (e.g., AgMg, AgYb, or MgYb). In other embodiments, the second electrodes EL2-1 and EL2-2 may have a multilayer structure which includes a reflective or semi-transmissive layer formed of the above-described materials. For example, the second electrodes EL2-1 and EL2-2 may include a transparent conductive film including at of indium tin oxide (ITO), indium zinc oxide (IZO), zinc oxide (ZnO), and indium tin zinc oxide (ITZO), or the like, or a combination thereof. For example, the second electrodes EL2-1 and EL2-2 may include the aforementioned metal material, a combination of at least two selected from the aforementioned metal materials, or an oxide of the aforementioned metal materials.

A first portion P1 of the 2-1-th electrode EL2-1 overlapping the 1-1-th electrode EL1-1 in a plan view may be parallel to the 1-1-th electrode EL1-1. For example, the thickness D1 of the first hole transport region HTR-1 may be uniform in the region overlapping the first portion P1 in a plan view, the thickness D2 of the first light emitting layer EML-1 may be uniform in the region overlapping the first portion P1 in a plan view, and the thickness D3 of the first electron transport region ETR-1 may be uniform in the region overlapping the first portion P1 in a plan view. A second portion P2 of the 2-2-th electrode EL2-2 overlapping the 1-2-th electrode EL1-2 in a plan view may be parallel to the 1-2-th electrode EL1-2. For example, the thickness D1_M of the second hole transport region HTR-2 may be uniform in the region overlapping the second portion P2 in a plan view, the thickness D2_M of the second light emitting layer EML-2 may be uniform in the region overlapping the second portion P2 in a plan view, and the thickness D3_M of the second electron transport region ETR-2 may be uniform in the region overlapping the second portion P2 in a plan view. For example, at least one of the thicknesses D1, D2, D3, D1_M, D2_M, and D3_M may be different from other ones thereof. In other embodiments, the thicknesses D1, D2, D3, D1_M, D2_M, and D3_M may be substantially the same.

The pixel defining film PDL may be disposed on the circuit layer DP-CL. The first and second openings PDL-OP1 and PDL-OP2 may be defined in the pixel defining film PDL. The first opening PDL_OP1 may expose an upper surface of the 1-1-th electrode EL1-1, and the second opening PDL_OP2 may expose an upper surface of the the 1-2-th electrode EL1-2. The pixel defining film PDL may divide the light emitting elements ED1 and ED2 (e.g., adjacent ones of the light emitting elements ED1 and ED2). The light emitting layers EML-1 and EML-2 of the light emitting elements ED1 and ED2 may be disposed and divided in the openings PDL-OP1 and PDL-OP2 defined in the pixel defining film PDL. In an embodiment of the disclosure, the hole transport regions HTR-1 and HTR-2, and the electron transport regions ETR-1 and ETR-2, of the light emitting elements ED1 and ED2 may be disposed in the openings PDL-OP1 and PDL-OP2 defined in the pixel defining film PDL. For example, the first hole transport region HTR-1 and the first electron transport region ETR-1 of the first light emitting element ED1 may be disposed in the first opening PDL-OP1, and the second hole transport region HTR-2 and the second electron transport region ETR-2 of the second light emitting element ED2 may be disposed in the second opening PDL-OP2.

The pixel defining film PDL may be formed of a polymer resin. For example, the pixel defining film PDL may be formed a material including at least one of a polyacrylate-based resin and a polyimide-based resin. In other embodiments, the pixel defining film PDL may include an inorganic material and the above-described polymer resin. The pixel defining film PDL may include a light absorbing material. For example, the pixel defining film PDL may include a black pigment or a black dye. In case that the pixel defining film PDL includes the black pigment or black dye, the pixel defining film PDL may form a black pixel defining film. In forming the pixel defining film PDL, a carbon black or the like may be used as the black pigment or the black dye, but an embodiment of the disclosure is not limited thereto.

The pixel defining film PDL may be formed of an inorganic material. For example, the pixel defining film PDL may include silicon nitride (SiNx), silicon oxide (SiOx) and silicon oxynitride (SiOxNy), or the like, or a combination thereof.

The encapsulation layer TFE may be disposed on the light emitting element layer DP-ED and cover the light emitting element layer DP-ED. The encapsulation layer TFE may include a structure (e.g., a triple layer structure) of inorganic layer/organic layer/inorganic layer which are stacked in sequence, but the layers constituting the encapsulation layer TFE are not limited thereto.

The inorganic layers of the encapsulation layer TFE may protect the light emitting element layer DP-ED from moisture and oxygen, and the organic layer of the encapsulation layer TFE may protect the light emitting element layer DP-ED from foreign substances such as dust particles. The inorganic layers of the encapsulation layer TFE may include silicon nitride layer, silicon oxynitride layer, silicon oxide layer, titanium oxide layer, aluminum oxide layer, or the like, or a combination thereof. The organic layer of the encapsulation layer TFE may include an acrylic organic layer, but is not limited thereto.

A light control panel OP may be disposed on the display panel DP, and include at least one of a light control layer and an anti-reflection layer. The light control layer may convert the wavelength of light emitted from the light emitting elements ED1 and ED2. The anti-reflection layer may control a reflected light by external light, or a reflected light generated by circuit layer configuration or the like inside the display panel DP.

In case that all of the first and second light emitting elements ED1 and ED2 emit blue light, the display device DD may include a light control panel OP. The light control panel OP may include a light control layer including a photoconverter. The light control layer of the light control panel OP may be a layer including a photoconverter such as quantum dots, a phosphor, or the like, or a combination thereof. The light control layer may include a first light control part including a red photoconverter for converting blue light into red light, and a second light control part including a green photoconverter for converting blue light into green light.

In case that all of the first and second light emitting elements ED1 and ED2 emit blue light, the light control panel OP may further include an anti-reflection layer disposed on the light control layer. The anti-reflection layer may include a polarizing layer or a color filter layer having a filter part which transmits or absorbs light having a partial wavelength range. In case that all of the first and second light emitting elements ED1 and ED2 emit blue light, the anti-reflection layer may be omitted from the light control panel OP.

In an embodiment of the disclosure, in case that the first and second light emitting elements ED1 and ED2 emit light having different wavelength ranges, the light control panel OP may not include the light control layer but may include only the anti-reflection layer. In the display device DD according to an embodiment, the light control panel OP may be omitted.

The base substrate BL may be disposed on the light control panel OP. The base substrate BL may be an inorganic layer, an organic layer, or a composite material layer. Unlike what is illustrated, in an embodiment, the base substrate BL may be omitted.

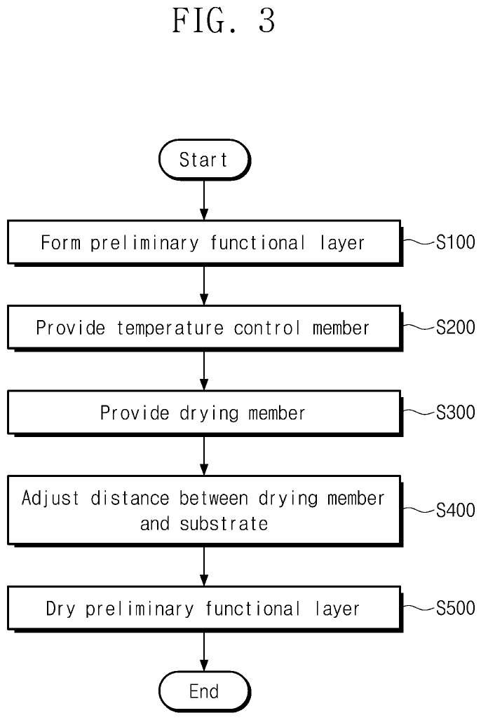

FIG. 3 is a flowchart schematically illustrating a method of manufacturing a display device according to an embodiment of the disclosure.

Referring to FIG. 3, the method of manufacturing the display device may include forming a preliminary functional layer (S100), providing a temperature control member (S200), providing a drying member (S300), adjusting a distance between the drying member and a substrate (S400), and drying the preliminary functional layer (S500).

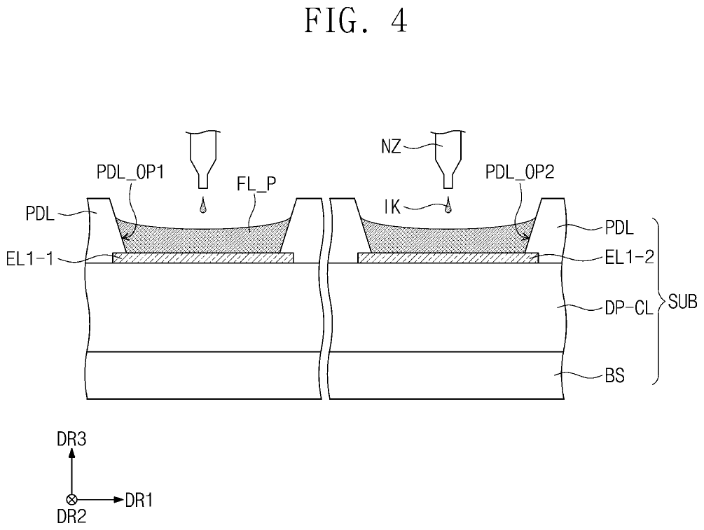

FIG. 4 is a schematic diagram illustrating a part of a method of manufacturing the display device according to an embodiment of the disclosure.

Referring to FIGS. 3 and 4, ink containing a solvent may be discharged onto the substrate SUB, and a preliminary functional layer FL_P may be formed (S100). The forming of the preliminary functional layer FL_P may be performed using an inkjet printing method.

The substrate SUB may include the base layer BS, the circuit layer DP-CL, the first electrodes EL1-1 and EL1-2, and the pixel defining film PDL. An ink IK for forming the preliminary functional layer FL_P may be provided, using a nozzle NZ of the inkjet printing apparatus, in the first and second openings PDL_OP1 and PDL_OP2 of the pixel defining film PDL.

The ink IK for forming the preliminary functional layer FL_P may be a material for the hole transport regions HTR-1 and HTR-2 (e.g., refer to FIG. 2), a material for the light emitting layers EML-1 and EML-2 (e.g., refer to FIG. 2), or a material for the electron transport layers ETR-1 and ETR-2 (e.g., refer to FIG. 2). The material for the hole transport regions HTR-1 and HTR-2, the material for light emitting layers EML-1 and EML-2, and the material for the electron transport regions ETR-1 and ETR-2 may be sequentially provided through the inkjet printing method. For example, the preliminary functional layer FL_P may be the hole transport regions HTR-1 and HTR-2, the light emitting layers EML-1 and EML-2, or the electron transport regions ETR-1 and ETR-2.

FIG. 4 schematically illustrates the preliminary functional layer FL_P formed on the 1-1-th electrode EL1-1 exposed by the first opening PDL_OP1, and on the 1-2-th electrode EL1-2 exposed by the second opening PDL_OP2, but an embodiment of the disclosure is not limited thereto. For example, in case that the preliminary functional layer FL_P is the light emitting layers EML-1 and EML-2, the ink IK may be discharged onto the hole transport regions HTR-1 and HTR-2. For example, in case that the preliminary functional layer FL_P is the electron transport regions ETR-1 and ETR-2, the ink IK may be discharged onto the light emitting layers EML-1 and EML2.

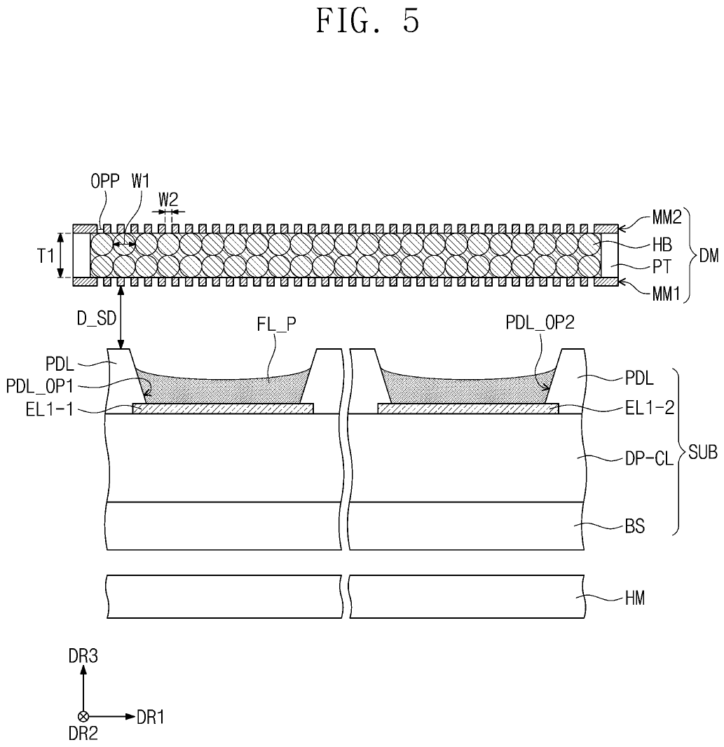

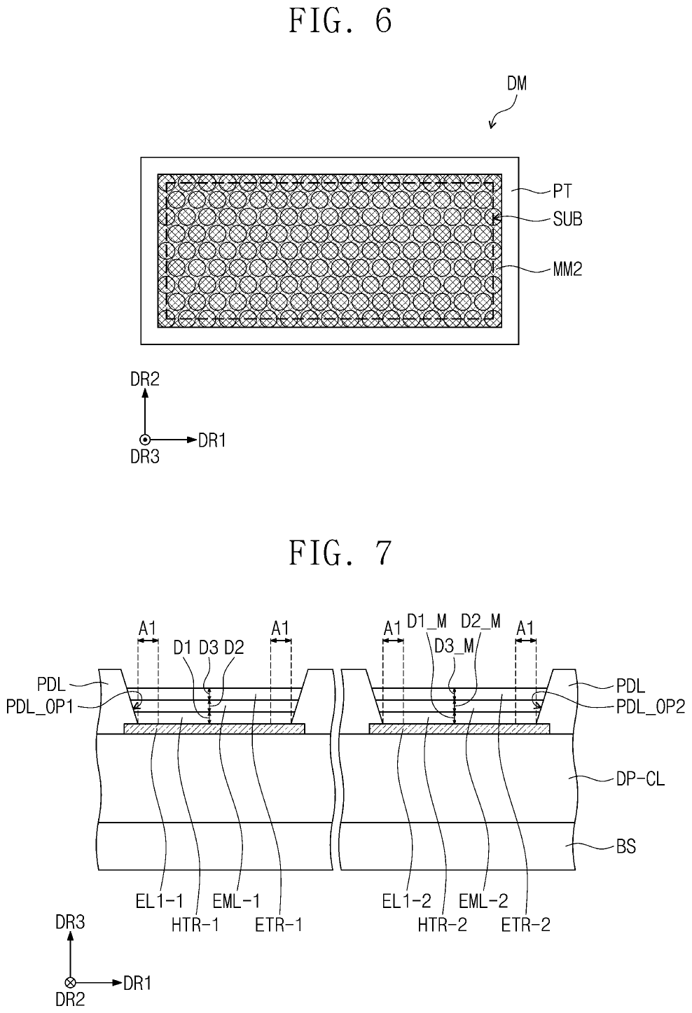

FIG. 5 is a schematic diagram illustrating a part of the method of manufacturing the display device according to an embodiment of the disclosure. FIG. 6 is a schematic plan view illustrating the drying member DM and the substrate SUB according to an embodiment of the disclosure.

Referring to FIGS. 3 and 5, the temperature control member HM may be provided on a lower surface of the substrate SUB (S200), and the drying member DM may be provided on the upper surface of the substrate SUB (S300). The temperature control member HM may provide heat to the substrate SUB. The temperature control member HM may control the temperature of the substrate SUB by cooling or heating the substrate SUB. The distance D_SD between the drying member DM and the substrate SUB may be adjusted (S400).

Referring to FIGS. 5 and 6, the drying member DM may include an outer plate PT and thermally conductive balls HB, a first mesh member MM1, and a second mesh member MM2. The thermally conductive balls HB may include silicon oxide polymers. The outer plate PT may surround the thermally conductive balls HB. A thickness T1 of the outer plate PT may be adjustable in the height direction. The thickness T1 of the outer plate PT may vary according to the ink IK discharged onto the substrate SUB. The thickness T1 of the outer plate PT may be in a range of about 5 mm to about 1 cm. The thickness T1 of the outer plate PT may correspond to a stacked height of the thermally conductive balls HB. The height of the thermally conductive balls HB may be adjusted to adjust a pressure difference (e.g., a pressure difference of the thermally conductive balls HB in a same layer). In case that a pressure difference occurs on the same layer, the degree of drying may be different for each region, and uniformity within the same layer may be lowered.

In case that the thermally conductive balls HB are configured as multiple layers, a heat capacity of the drying member DM may become higher. After the drying member DM reaches a temperature (e.g., a predetermined or selectable temperature), heat may be uniformly transferred downward to uniformly vaporize the solvent in the ink IK. Although FIG. 5 illustrates that the number of layers of the thermally conductive balls HB is 2, the number of layers of the thermally conductive balls HB is not limited thereto.

The first mesh member MM1 may be attached to a lower surface of the outer plate PT, and the second mesh member MM2 may be attached to an upper surface of the outer plate PT. For example, the thermally conductive balls HB may be disposed in a space surrounded by the outer plate PT, the first mesh member MM1, and the second mesh member MM2. The openings OPP may be defined in the first mesh member MM1 and the second mesh member MM2. A width W2 of each of the openings OPP may be smaller than a diameter W1 of each of the thermally conductive balls HB.

In a plan view, the substrate SUB may overlap (e.g., completely overlap) the drying member DM in a plan view. Since the thermally conductive balls HB are densely arranged, the substrate SUB may be invisible when viewed from the upper surface of the drying member DM. The distance D_SD between the drying member DM and substrate SUB may be in a range of about 10 mm to about 100 mm.

The preliminary functional layer FL_P may be dried by the drying member DM (S500). The drying member DM may have a large heat capacity. Accordingly, the drying member DM may absorb heat from the substrate SUB and provide the heat evenly to the surface (e.g., the entire surface) of the substrate SUB. The drying member DM and the substrate SUB may be disposed in a drying chamber (not shown) and a uniform pressure may be applied to the substrate SUB. At this time, the substrate SUB may have a structure enclosed by a drying chamber (not shown) and a pressure difference may be produced on a side surface of the substrate SUB. The solvent included in the ink IK may be vaporized by uniform heat and pressure, and the vaporized solvent may pass through the thermally conductive balls HB. As a result, the preliminary functional layer FL_P may be dried uniformly regardless of the size of the substrate SUB.

FIG. 7 is a schematic diagram illustrating a part of the method of manufacturing the display device according to an embodiment of the disclosure. FIG. 7 is a diagram illustrating the substrate SUB dried by the drying member DM.

Referring to FIG. 7, the first hole transport region HTR-1, the first light emitting layer EML-1, and the first electron transport region ETR-1 may be formed in the first opening PDL_OP1, and the second hole transport region HTR-2, the second light emitting layer EML-2, the second electron transport region ETR-2 may be formed in the second opening PDL_OP2. The hole transport regions HTR-1 and HTR-2, the light emitting layers EML-1 and EML-2, and the electron transport regions ETR-1 and ETR-2 may be formed by the method of manufacturing the display device illustrated in FIGS. 3 to 6.

The thickness D1 of the first hole transport region HTR-1 may be uniform in the first opening PDL_OP1, and the thickness D1_M of the second hole transport region HTR-2 may be uniform in the second opening PDL_OP2. The thickness D1 of the first hole transport region HTR-1 and the thickness D1_M of the second hole transport region HTR-2 may be substantially the same.

The thickness D2 of the first light emitting layer EML-1 may be uniform in the first opening PDL_OP1, and the thickness D2_M of the second light emitting layer EML-2 may be uniform in the second opening PDL_OP2. The thickness D2 of the first light emitting layer EML-1 and the thickness D2_M of the second light emitting layer EML-2 may be substantially the same.

The thickness D3 of the first electron transport region ETR-1 may be uniform in the first opening PDL_OP1, and the thickness D3_M of the second electron transport region ETR-2 may be uniform in the second opening PDL_OP2. The thickness D3 of the first electron transport region ETR-1 and the thickness D3_M of the second electron transport region ETR-2 may be substantially the same.

Within a first distance A1 from the pixel defining film PDL, the thickness D1 of the first hole transport region HTR-1, and the thickness D1_M of the second hole transport region HTR-2 may have a uniformity of about 1% or less. The first distance A1 may be about 5 μm. In FIG. 7, within the first distance A1, the thicknesses of the first hole transport region HTR-1 and the second hole transport region HTR-2 are illustrated. However, within the first distance A1, the thicknesses of the first and second light emitting layers EML-1 and EML-2 and the thickness of the first and second electron transport regions ETR-1 and ETR-2 may also have the uniformity of about 1% or less. For example, the preliminary functional layer FL_P (e.g., refer to FIG. 5) discharged onto the substrate SUB (e.g., refer to FIG. 5) may be uniformly dried by the drying member DM (e.g., refer to FIG. 5). The uniformity is a value expressed in percentage by dividing the difference between the maximum thickness and the minimum thickness by the sum of the maximum thickness and the minimum thickness.

The display device DD (e.g., refer to FIG. 1) manufactured by the method of manufacturing the display device of an embodiment of the disclosure may have a luminance uniformity of about 3% or less. The display device DD may have a white angle difference (WAD) of less than about 0.01. The WAD may indicate an index for evaluating a change in a white color characteristic according to an observation angle. For example, the WAD may be evaluated by measuring the amount of change in luminance and the amount of change in color coordinates according to an observation angle relative to the front observed in a direction perpendicular to the screen (e.g., the third direction, see FIG. 1). In case that the WAD is improved, the display quality of the display device DD may be improved.

According to an embodiment of the disclosure, the functional layers HTR-1, HTR-2, EML-1, EML-2, ETR-1, and ETR-2 in the display panel DP (e.g., refer to FIG. 2) may be dried uniformly by the drying member DM. The functional layers HTR-1, HTR-2, EML-1, EML-2, ETR-1, and ETR-2 in the edge region of the display panel DP and in the central region of the display panel DP may be uniformly dried, and the light emitting layers EML-1 and EML-2 in each pixel may also be uniformly dried. Therefore, the occurrence of dry spots on the display panel DP may be reduced or eliminated. Thus, the luminance uniformity and WAD characteristics of the display device DD (e.g., refer to FIG. 1) may be improved, and the display quality of the display device DD may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
discharging ink containing a solvent onto a substrate to form a preliminary functional layer;
providing a temperature control member on a lower surface of the substrate;
providing a drying member including a plurality of thermally conductive balls on an upper surface of the substrate; and
drying the preliminary functional layer by the drying member.

2. The method of claim 1, further comprising:
adjusting a distance between the drying member and the substrate.

3. The method of claim 1, wherein the solvent is vaporized and passes through the plurality of thermally conductive balls.

4. The method of claim 1, wherein the plurality of thermally conductive balls comprise a silicon oxide polymer.

5. The method of claim 1, wherein
the drying member further comprises an outer plate, and
the plurality of thermally conductive balls are surrounded by the outer plate.

6. The method of claim 5, wherein
the drying member further comprises:
a first mesh member attached to a lower surface of the outer plate; and
a second mesh member attached to an upper surface of the outer plate, and
the plurality of thermally conductive balls are disposed in a space surrounded by the outer plate, the first mesh member, and the second mesh member.

7. The method of claim 6, wherein
a plurality of openings are defined in the first mesh member and the second mesh member, and
a width of each of the plurality of openings is smaller than a diameter of each of the plurality of thermally conductive balls.

8. The method of claim 6, wherein the outer plate has a thickness in a range of about 5 mm to about 1 cm.

9. The method of claim 1, wherein a distance between the substrate and the drying member is in a range of about 10 mm to about 100 mm.

10. The method of claim 1, wherein the substrate completely overlaps the drying member in a plan view.

11. The method of claim 1, wherein the providing of the drying member comprises adjusting a height of the plurality of thermally conductive balls to adjust a pressure difference of the plurality of thermally conductive balls.

12. A display device comprising:
a circuit layer disposed on a base layer;
a first light emitting element disposed on the circuit layer and including:
a 1-1-th electrode;
a 1-1-th functional layer;
a first light emitting layer;
a 2-1-th functional layer; and
a 2-1-th electrode;
a second light emitting element disposed on the circuit layer and including:
a 1-2-th electrode;
a 1-2-th functional layer;
a second light emitting layer;
a 2-2-th functional layer; and
a 2-2-th electrode; and
a pixel defining film disposed on the circuit layer and including:
a first opening exposing a top surface of the 1-1-th electrode; and
a second opening exposing a top surface of the 1-2-th electrode, wherein
the 1-1-th electrode, the 1-1-th functional layer, the first light emitting layer, the 2-1-th functional layer, and the 2-1-th electrode are sequentially stacked,
the 1-1-th functional layer, the first light emitting layer, and the 2-1-th functional layer are disposed in the first opening,
the 1-2-th functional layer, the second light emitting layer, and the 2-2-th functional layer are disposed in the second opening,
a thickness of the 1-1-th functional layer is uniform in the first opening, and
a thickness of the 1-2-th functional layer is uniform in the second opening.

13. The display device of claim 12, wherein the thickness of the 1-1-th functional layer and the thickness of the 1-2-th functional layer are substantially the same.

14. The display device of claim 12, wherein a thickness of the 2-1-th functional layer and a thickness of the 2-2-th functional layer are substantially the same.

15. The display device of claim 12, wherein the 1-1-th functional layer, the first light emitting layer, and the 2-1-th functional layer are each provided through an inkjet printing method.

16. The display device of claim 12, wherein the 1-2-th functional layer, the second light emitting layer, and the 2-2-th functional layer are each provided through an inkjet printing method.

17. The display device of claim 12, wherein within a distance of about 5 micrometers from the pixel defining film, the thickness of the 1-1-th functional layer and the thickness of the 1-2-th functional layer have a uniformity of about 1% or less.

18. The display device of claim 12, wherein the 1-1-th electrode is parallel to a first portion of the 2-1-th electrode overlapping the 1-1-th electrode in a plan view.

19. The display device of claim 12, wherein the 1-2-th electrode is parallel to a second portion of the 2-2-th electrode overlapping the 1-2-th electrode in a plan view.

20. The display device of claim 12, wherein
a thickness of the 2-1-th functional layer is uniform in the first opening, and
a thickness of the 2-2-th functional layer is uniform in the second opening.
